(19) United States
(12) Patent Application Publication
(10) Pub. No.: US 2005/0029504 A1
(43) Pub. Date: Feb. 10, 2005

(54) Reducing parasitic conductive paths in phase change memories

(76) Inventor: Ilya V. Karpov, Santa Clara, CA (US)

Correspondence Address: TROP PRUNER & HU, PC, 8554 KATY FREEWAY, SUITE 100, HOUSTON, TX, 77024, US

(21) Appl. No.: 10/634,141

(22) Filed: Aug. 4, 2003

(51) Int. Cl. H01L 47/00; H01L 21/00

(52) U.S. Cl. 257/4; 438/95

(57) ABSTRACT

A phase change memory may be formed by defining a pore in an insulator over a semiconductor substrate. The pore may be filled with a metallic material to form a high resistance heater. A portion of the metallic material may be removed at the upper end of the pore. Thereafter, when the phase change material is deposited, a portion of the phase change material fills the upper end of the pore and the remainder of the phase change material overlies the pore and the insulator. A conductive material may be formed atop the phase change material. As a result, the creation of a parasitic path from a corner of the metallic heater to the overlying conductive material may be less likely.

### BACKGROUND

This invention relates generally to phase change memories.

Phase change memory devices use phase change materials, i.e., materials that may be electrically switched between a generally amorphous and a generally crystalline state, as an electronic memory. One type of memory element utilizes a phase change material that may be, in one application, electrically switched between generally amorphous and generally crystalline local orders or between the different detectable states of local order across the entire spectrum between completely amorphous and completely crystalline states.

Typical materials suitable for such an application include various chalcogenide elements. The state of the phase change materials is also non-volatile. When the memory is set in either a crystalline, semi-crystalline, amorphous, or semi-amorphous state representing a resistance value, that value is retained until reprogrammed, even if power is removed. This is because the program value represents a phase or physical state of the memory (e.g., crystalline or amorphous).

In phase change memories in which a metal heater fills a pore and a phase change material is formed over the pore, a parasitic conductive path may be created. This parasitic conductive path may extend from a corner of the metal heater in the pore to an overlying top electrode. Such a parasitic path may exist in a high resistivity state, sometimes calls a reset state.

Thus, there is a need for alternate ways to reduce partially conductive paths between heaters and overlying top electrodes past a phase change material in phase change memories.

### BRIEF DESCRIPTION OF THE DRAWINGS

FIG. 1 is an enlarged, partially schematic, partially cross-sectioned depiction of a phase change memory cell in accordance with one embodiment of the present invention;

FIG. 2 is an enlarged, cross-sectional view of another embodiment of the present invention;

FIG. 3 is an enlarged, cross-sectional view of the embodiment shown in FIG. 1 at an early stage of manufacture;

FIG. 4 is an enlarged, cross-sectional view corresponding to FIG. 3 at a subsequent stage of manufacture;

FIG. 5 is an enlarged, cross-sectional view corresponding to FIG. 4 at a subsequent stage of manufacture; and

FIG. 6 is a system schematic depiction of one embodiment of the present invention.

### DETAILED DESCRIPTION

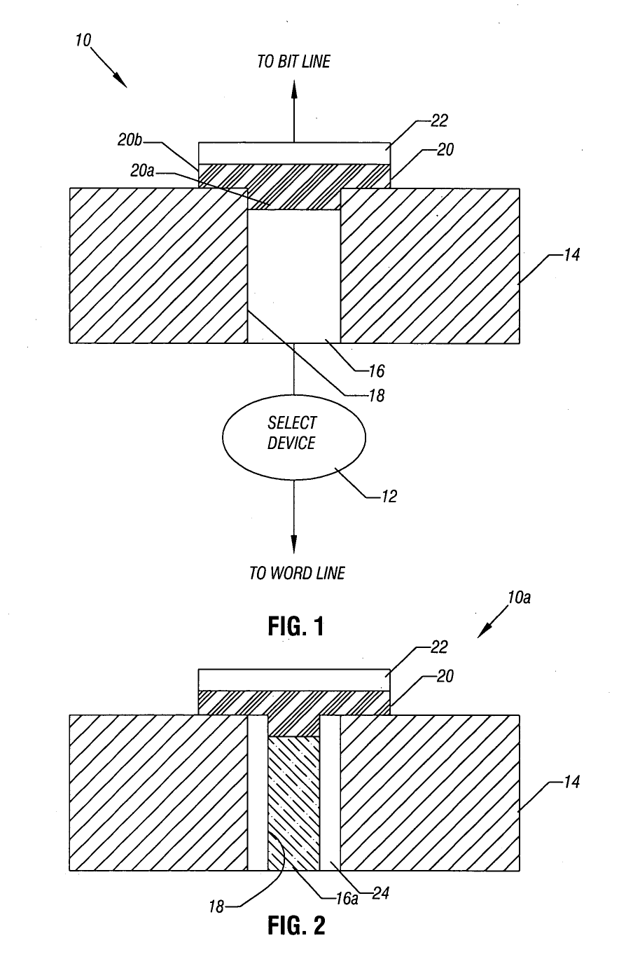

Referring to FIG. 1, a cell 10 may be part of a phase change memory. The cell 10 may be selected by a select device 12 coupled, for example, to a word line. In one example, the cell 10 may also be addressed through a bitline coupled to the cell 10. Thus, in some embodiments, transverse conductive lines, such as row and bitlines, may be used to select one cell from an array that includes a large number of cells.

A pore 18 may be defined as a hole in an insulating material 14 formed over a semiconductor substrate. Intervening layers may be provided between the material 14 and the substrate. The pore 18 may be partially and substantially, but not completely, filled by a metal heater 16 coupled, at least indirectly, to the select device 12.

A phase change material 20 may include a lower portion 20a which extends into the pore 18 and an upper portion 20b that rests over the insulating material 14 in some embodiments of the present invention. As a result, a T-shaped phase change material 20 is produced in some embodiments. An overlying conductive top electrode 22 may provide an electrical connection to a bitline or other conductive line to enable the cell 10 to be addressed.

As a result of the configuration shown in FIG. 1, the creation of a parasitic conductive path between the metal heater 16 and the top electrode 22 may be either reduced or effectively eliminated. Namely, a parasitic conductive path is not readily created between an upper corner of the metallic heater 16 and the overlying electrode 22 because of the imposition of the lower portion 20a of the phase change material 20 within the pore 18.

In one embodiment, the phase change material 20 may be a non-volatile, phase change material. A phase change material may be a material having electrical properties (e.g., resistance) that may be changed through the application of energy such as, for example, heat, light, voltage potential, or electrical current.

Examples of phase change materials may include a chalcogenide material or an ovonic material. An ovonic material may be a material that undergoes electronic or structural changes and acts as a semiconductor once subjected to application of a voltage potential, electrical current, light, heat, etc. A chalcogenide material may be a material that includes at least one element from column VI of the periodic table or may be a material that includes one or more of the chalcogen elements, e.g., any of the elements of tellurium, sulfur, or selenium. Ovonic and chalcogenide materials may be non-volatile memory materials that may be used to store information.

In one embodiment, the memory material may be chalcogenide element composition from the class of tellurium-germanium-antimony (TeₓGe_{y}Sb_{z}) material or a GeSbTe alloy, although the scope of the present invention is not limited to just these materials.

In one embodiment, if the memory material is a non-volatile, phase change material, the memory material may be programmed into one of at least two memory states by applying an electrical signal to the memory material. An electrical signal may alter the phase of the memory material between a substantially crystalline state and a substantially amorphous state, wherein the electrical resistance of the memory material in the substantially amorphous state is greater than the resistance of the memory material in the substantially crystalline state. Accordingly, in this embodiment, the memory material may be adapted to be altered to one of at least two resistance values within a range of resistance values to provide single bit or multi-bit storage of information.

Programming of the memory material to alter the state or phase of the material may be accomplished by applying voltage potentials to the electrode 22 and heater 16, thereby generating a voltage potential across the memory material 20. An electrical current may flow through a portion of the memory material 20 and may result in heating of the memory material 20.

This heating and subsequent cooling may alter the memory state or phase of the memory material 20. Altering the phase or state of the memory material 20 may alter an electrical characteristic of the memory material 20. For example, resistance of the material 20 may be altered by altering the phase of the memory material 20. The memory material may also be referred to as a programmable resistive material or simply a programmable material.

In one embodiment, a voltage potential difference of about 3 volts may be applied across a portion of the memory material by applying about 3 volts to the heater 16 and about zero volts to an electrode 22. A current flowing through the memory material 20 in response to the applied voltage potentials may result in heating of the memory material. This heating and subsequent cooling may alter the memory state or phase of the material.

In a “reset” state, the memory material may be in an amorphous or semi-amorphous state and in a “set” state, the memory material may be in a crystalline or semi-crystalline state. The resistance of the memory material in the amorphous or semi-amorphous state may be greater than the resistance of the material in the crystalline or semi-crystalline state. The association of reset and set with amorphous and crystalline states, respectively, is a convention. Other conventions may be adopted.

Due to electrical current, the memory material may be heated to a relatively higher temperature to amorphisize memory material and “reset” memory material (e.g., program memory material to a logic “0” value). Heating the volume or memory material to a relatively lower crystallization temperature may crystallize memory material and “set” memory material (e.g., program memory material to a logic “1” value). Various resistances of memory material may be achieved to store information by varying the amount of current flow and duration through the volume of memory material.

The information stored in memory material 20 may be read by measuring the resistance of the memory material. As an example, a read current may be provided to the memory material using electrode 22 and select device 12 and a resulting read voltage across the memory material may be compared against a reference voltage using, for example, a sense amplifier (not shown). The read voltage may be proportional to the resistance exhibited by the memory storage element. Thus, a higher voltage may indicate that memory material is in a relatively higher resistance state, e.g., a “reset” state. A lower voltage may indicate that the memory material is in a relatively lower resistance state, e.g., a “set” state.

In accordance with another embodiment of the present invention, shown in FIG. 2, substantially the same structure may be utilized with the exception that a sidewall spacer 24 may be provided within the pore 18. The spacer 24 may be formed of an insulating material that is anisotropically etched, in one embodiment.

As a result, a slightly smaller metal heater 16a results in an opening may be created by the sidewall spacer 24. The opening defined by the spacer 24 may be smaller than that available within the limits of the available lithography. Like the embodiment shown in FIG. 1, the creation of a parasitic conductive path between the metallic heater 16a and the overlying conductor 22 is made less likely.

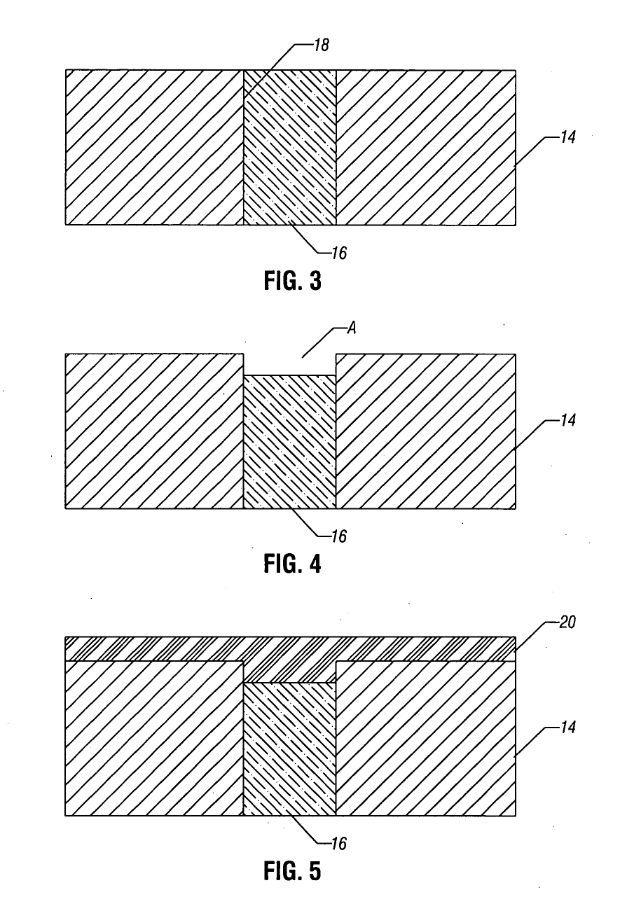

Referring to FIG. 3, an insulating material 14 may be formed over a semiconductor substrate and a pore 18 may be formed therein, for example, using conventional etching techniques. The pore 18 then may be filled with a heater 16, which may be formed of a high resistance metallic material. In some embodiments, a spacer may be formed in the pore 18 prior to the filling with the high resistance metal to form the metallic heater 16. After metal fill, the entire structure may then be planarized and polished to achieve the configuration as shown in FIG. 3.

Thereafter, as shown in FIG. 4, a recess A may be formed by dry or wet etching, for example. In effect, a portion of the metallic material utilized to form the heater 16 may be dipped back or removed to form the recess A.

A phase change material 20 may then be deposited so as to fill the recess A and to overlie the insulator 14 as shown in FIG. 5. Thereafter, a top electrode 22 may be deposited and the electrode 22 and upper portion 20b of the phase change material 20 may be defined and etched to create the structure shown in FIG. 1 or FIG. 2.

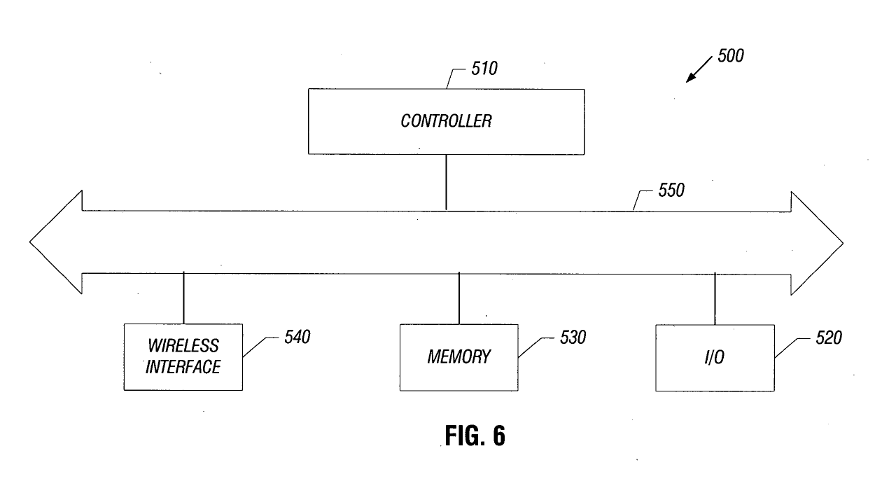

Turning to FIG. 6, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, or a cellular network, although the scope of the present invention is not limited in this respect.

System 500 may include a processor-based device 510, such as a controller, an input/output (I/O) device 520 (e.g. a keypad, display), a memory 530, and a wireless interface 540 coupled to each other via a bus 550. It should be noted that the scope of the present invention is not limited to embodiments having any or all of these components.

The device 510 may comprise, for example, one or more microprocessors, digital signal processors, microcontrollers, or the like. Memory 530 may be used to store messages transmitted to or by system 500. Memory 530 may also optionally be used to store instructions that are executed by the device 510 during the operation of system 500, and may be used to store user data. Memory 530 may be provided by one or more different types of memory. For example, memory 530 may comprise a volatile memory (any type of random access memory), a non-volatile memory such as a flash memory, and/or phase change memory that includes a memory element cell 10 illustrated in FIG. 1.

The I/O device 520 may be used to generate a message. The system 500 may use the wireless interface 540 to transmit and receive messages to and from a wireless communication network with a radio frequency (RF) signal. Examples of the wireless interface 540 may include an antenna, or a wireless transceiver, such as a dipole antenna, although the scope of the present invention is not limited in this respect.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
forming a pore in an insulator;
forming a heater in said pore by filling said pore with a conductive material and then removing the upper portion of said conductive material;
filling the upper portion with a phase change material that extends over said insulator;
forming a substantially planar upper surface of said phase change material; and
forming a substantially planar upper electrode over said substantially planar upper surface of said phase change material.

2-3. (Canceled).

4. The method of claim 1 including planarizing the upper surface of said insulator.

5-6. (Canceled).

7. The method of claim 1 including patterning and etching said phase change material over said insulator.

8. The method of claim 7 including forming a T-shaped phase change material.

9. The method of claim 3 including forming a sidewall spacer in said pore.

10. The method of claim 9 including depositing metal in said pore after forming said sidewall spacer.

11. An apparatus comprising:
an insulator having a pore formed in said insulator;
a heater formed in said pore;
a phase change material over said insulator and extending into said pore, said phase change material having a substantially planar upper surface; and
a substantially planar conductive layer formed over said phase change material.

12. The apparatus of claim 11 wherein said phase change material is arranged in said pore to reduce the occurrence of parasitic conductive paths.

13. The apparatus of claim 11 wherein said phase change material is T-shaped.

14. The apparatus of claim 11 including a sidewall spacer in said pore.

15. The apparatus of claim 11 wherein said pore is substantially filled by said heater.

16. The apparatus of claim 11 wherein said heater is metallic.

17. The apparatus of claim 11 including an electrode over said phase change material.

18. The apparatus of claim 11 wherein said phase change material is an ovonic material.

19. The apparatus of claim 11 wherein said phase change material is a chalcogenide.

20. The apparatus of claim 11 wherein the entire upper extent of said pore is filled with said phase change material.

21. A system comprising:
a processor-based device; and
a semiconductor memory coupled to said device, said memory including an insulator having a pore formed in said insulator, a heater formed in said pore, a phase change material over said insulator and extending into said pore, said phase change material having a substantially planar upper surface and a substantially planar conductive layer over said phase change material.

22. (Canceled).

23. The system of claim 21 wherein said phase change material is T-shaped.

24. The system of claim 21 wherein said phase change material is arranged to reduce the occurrence of parasitic conductive paths.

25. The system of claim 21 wherein said phase change material is arranged in the upper extent of said pore to prevent the occurrence of a parasitic conductive path through said pore past said phase change material.

26. The system of claim 21 wherein said phase change material is an ovonic material.

27. The system of claim 21 wherein said phase change material is a chalcogenide.

28. The system of claim 21 including a sidewall spacer in said pore.

29. The system of claim 21 wherein said heater substantially fills said pore.

30. The system of claim 21 wherein said heater is metallic.

31. The system of claim 21 including an electrode over said phase change material.
